(19) United States
(12) Patent Application Publication
(10) Pub. No.: US 2023/0215873 A1
(43) Pub. Date: Jul. 6, 2023

(54) DISPLAY DEVICE

(71) Applicant: LG Display Co., Ltd., Seoul (KR)

(72) Inventors: MyungSub LIM, Seoul (KR); Sujin HAM, Seoul (KR); HaeYoon JUNG, Seoul (KR)

(21) Appl. No.: 17/985,672

(22) Filed: Nov. 11, 2022

(30) Foreign Application Priority Data
Dec. 31, 2021 (KR) 10-2021-0194564

(51) Int. Cl. H01L 27/12; H01L 25/16

(52) U.S. Cl. CPC H01L 27/124; H01L 25/167; H01L 24/32

(57) ABSTRACT

A display device according to an example embodiment of the present disclosure may include a stretchable lower substrate, a pattern layer disposed on the lower substrate and including a plurality of plate patterns and a plurality of line patterns, a plurality of pixels disposed on each of the plurality of plate patterns, and a plurality of connection lines connecting the plurality of pixels. The plurality of connection lines are disposed on each of the plurality of line patterns, so that stretching reliability may be improved.

### CROSS-REFERENCE TO RELATED APPLICATIONS

This application claims the benefit of and priority to Korean Patent Application No. 10-2021-0194564 filed on Dec. 31, 2021 in the Republic of Korea, the entire contents of which are hereby expressly incorporated by reference into the present application.

### BACKGROUND

### Technical Field

The present disclosure relates to a display device, and more particularly, to a stretchable display device.

### Description of the Related Art

Display devices used for a computer monitor, a TV, a mobile phone, and the like include an organic light emitting display (OLED) that emits light by itself, a liquid-crystal display (LCD) that requires a separate light source, and the like.

Such display devices are being applied to more and more various fields including not only a computer monitor and a TV, but personal mobile devices, and thus, display devices having a reduced volume and weight while having a wide active area are being studied.

Recently, a display device manufactured to be stretchable in a specific direction and changeable into various shapes by forming a display unit, lines, and the like on a flexible substrate such as plastic that is a flexible material has received considerable attention as a next-generation display device.

### BRIEF SUMMARY

One or more embodiments of the present disclosure provide a display device capable of reducing or minimizing a stress of stretched lines.

One or more embodiments of the present disclosure provide a display device allowing for an improvement in stretching rate.

Technical benefits of the present disclosure are not limited to the above-mentioned benefits, and other benefits, which are not mentioned above, can be clearly understood by those skilled in the art from the following descriptions.

A display device according to an example embodiment of the present disclosure may include a stretchable lower substrate; a pattern layer disposed on the lower substrate and including a plurality of plate patterns and a plurality of line patterns; a plurality of pixels disposed on each of the plurality of plate patterns; and a plurality of connection lines connecting the plurality of pixels, wherein the plurality of connection lines are disposed on each of the plurality of line patterns, so that stretching reliability may be improved.

Other detailed matters of the example embodiments are included in the detailed description and the drawings.

According to the present disclosure, a stretching rate of a display device can be improved by disposing a plurality of connection lines on one line pattern.

According to the present disclosure, a buffer hole and a filling member can distribute stretching stress applied in a curved area.

According to the present disclosure, cracks in connection lines can be reduced or minimized by disposing the connection lines on a neutral plane of a curved area.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a plan view of a display device according to an example embodiment of the present disclosure.

FIG. 2 is an enlarged plan view of an active area of the display device according to an example embodiment of the present disclosure.

FIG. 3 is a cross-sectional view taken along cutting line shown in FIG. 2.

FIG. 4 is a cross-sectional view taken along cutting line IV-IV′ shown in FIG. 2.

FIG. 5 is a cross-sectional view taken along cutting line V-V′ shown in FIG. 2.

FIG. 6 is a circuit diagram of a sub-pixel of the display device according to an example embodiment of the present disclosure.

FIG. 7 is a view illustrating connection lines of the display device according to an example embodiment of the present disclosure.

FIG. 8 is a cross-sectional view taken along line VIII-VIII′ of FIG. 7.

FIG. 9 is a view illustrating connection lines of a display device according to another example embodiment of the present disclosure.

FIG. 10A is a cross-sectional view taken along line X-X′ of FIG. 9 according to one example embodiment of the present disclosure.

FIG. 10B is a cross-sectional view taken along line X-X′ of FIG. 9 according to another example embodiment of the present disclosure.

FIG. 11 is a view illustrating connection lines of a display device according to still another example embodiment of the present disclosure.

### DETAILED DESCRIPTION

The advantages and features of the present disclosure, and methods for accomplishing the same will be more clearly understood from example embodiments described below with reference to the accompanying drawings. However, the present disclosure is not limited to the following example embodiments but may be implemented in various different forms. The example embodiments are provided only to complete disclosure of the present disclosure and to fully provide a person with ordinary skill in the art to which the present disclosure pertains with the category of the present disclosure.

The shapes, dimensions, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on,” “above,” “below,” and “next”, one or more parts may be positioned between the two parts unless the terms are used with the term “immediately” or “directly.”

When an element or layer is referred to as being “on” another element or layer, it may be directly on the other element or layer, or intervening elements or layers may be present.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

Throughout the whole specification, the same reference numerals denote the same elements.

Since the dimensions and thickness of each component illustrated in the drawings are represented for convenience in explanation, the present disclosure is not necessarily limited to the illustrated dimensions and thickness of each component.

The features of various embodiments of the present disclosure can be partially or entirely coupled to or combined with each other and can be interlocked and operated in technically various ways, and the embodiments can be carried out independently of or in association with each other.

Hereinafter, various example embodiments of the present disclosure will be described in detail with reference to the accompanying drawings.

A display device according to an example embodiment of the present disclosure is a display device capable of displaying an image even if it is bent or stretched, and may also be referred to as a display device, a stretchable display device or a flexible display device. The display device may have higher flexibility and stretchability than conventional, typical display devices. Accordingly, a user can bend or stretch the display device, and a shape of the display device can be freely changed according to the user's manipulation. For example, when the user grabs and pulls an end of the display device, the display device may be stretched in a pulling direction by the user. If the user places the display device on an uneven outer surface, the display device can be disposed to be bent according to a shape of the outer surface. When force applied by the user is removed, the display device can return to an original shape thereof.

### Stretchable Substrate and Pattern Layer

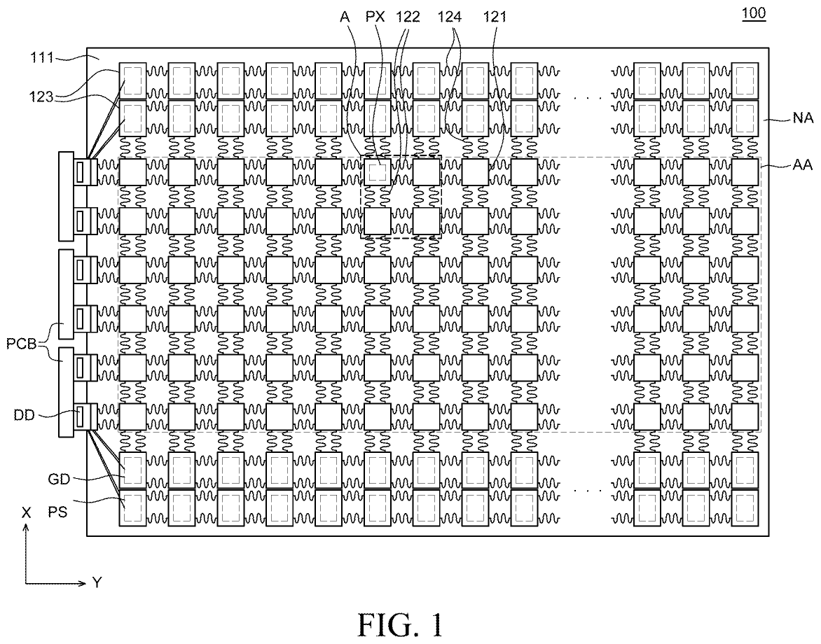

FIG. 1 is a plan view of a display device according to an example embodiment of the present disclosure.

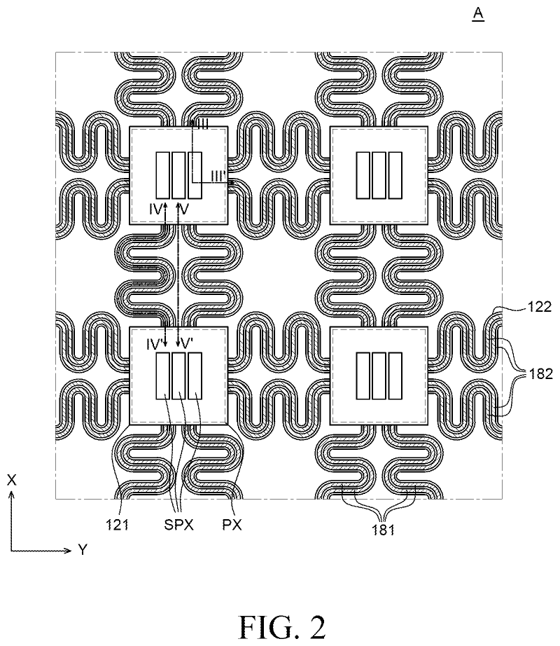

FIG. 2 is an enlarged plan view of an active area of the display device according to an example embodiment of the present disclosure.

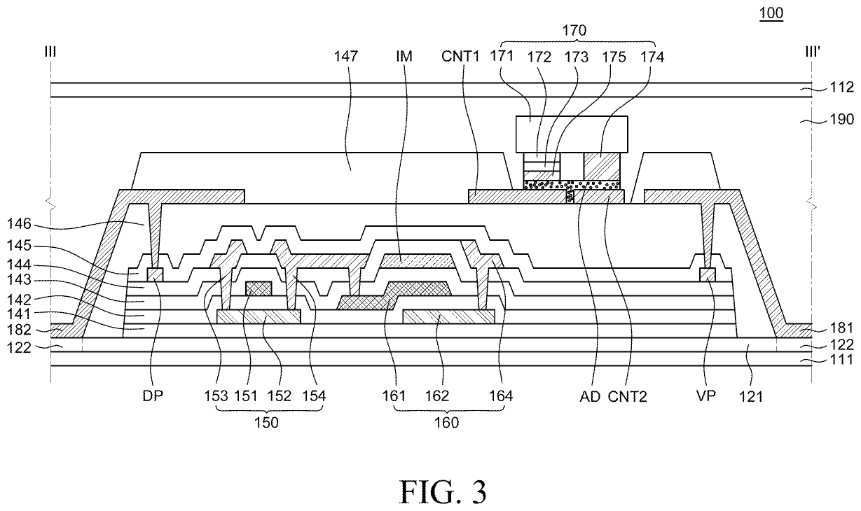

FIG. 3 is a cross-sectional view taken along cutting line shown in FIG. 2.

Specifically, FIG. 2 is an enlarged plan view of area A shown in FIG. 1.

Referring to FIG. 1, a display device 100 according to an example embodiment of the present disclosure may include a lower substrate 111, a pattern layer 120, a plurality of pixels PX, gate drivers GD, data drivers DD, and power supplies PS. And, referring to FIG. 1, the display device 100 according to an example embodiment of the present disclosure may further include a filling layer 190 and an upper substrate 112.

The lower substrate 111 is a substrate for supporting and protecting various components of the display device 100. In addition, the upper substrate 112 is a substrate for covering and protecting various components of the display device 100. That is, the lower substrate 111 is a substrate that supports the pattern layer 120 on which the pixels PX, the gate drivers GD, and the power supplies PS are formed. In addition, the upper substrate 112 is a substrate that covers the pixels PX, the gate drivers GD, and the power supplies PS.

Each of the lower substrate 111 and the upper substrate 112 is a ductile substrate and may be formed of an insulating material that can be bent or stretched. For example, each of the lower substrate 111 and the upper substrate 112 may be formed of silicone rubber such as polydimethylsiloxane (PDMS) or elastomers such as polyurethane (PU) and polytetrafluoroethylene (PTFE), and thus, may have flexible properties. In addition, materials of the lower substrate 111 and the upper substrate 112 may be the same, but are not limited thereto and may be variously modified.

Each of the lower substrate 111 and the upper substrate 112 is a ductile substrate and may be reversibly expandable and contractible. Accordingly, the lower substrate 111 may be referred to as a lower stretchable substrate, a lower flexible substrate, a lower extendable substrate, a lower ductile substrate, a first stretchable substrate, a first flexible substrate, a first extendable substrate, or a first ductile substrate, and the upper substrate 112 may be referred to as an upper stretchable substrate, an upper flexible substrate, an upper extendable substrate, an upper ductile substrate, a second stretchable substrate, a second flexible substrate, a second extendable substrate, or a second ductile substrate. Further, moduli of elasticity of the lower substrate 111 and the upper substrate 112 may be several MPa to several hundreds of MPa. Further, a ductile breaking rate of the lower substrate 111 and the upper substrate 112 may be 100% or higher. Here, the ductile breaking rate refers to a stretching rate at a time when an object to be stretched is broken or cracked. In other words, the ductile breaking rate refers to an extension distance when an object to be stretched is broken or cracked. That is, the ductile breaking rate is defined as a percentage ratio of a length of an original object and a length of the stretched object when an object has been stretched sufficiently that it is considered broken. For example, if a length of an object (e.g., lower substrate 111) is 100 cm when the object is not stretched and then, it reaches a length of 110 cm when the object has been stretched enough that it becomes broken or cracked at this length, then it has been stretched to 110% of its original length. In this case, the ductile breaking rate of the object is 110%. The number could thus also be called a ductile breaking ratio since it is a ratio of the stretched length as the numerator compared to the original upstretched length as the denominator at the time the break occurs.

A thickness of the lower substrate may be 10 μm to 1 mm, but is not limited thereto.

The lower substrate 111 may have an active area AA and a non-active area NA surrounding the active area AA. However, the active area AA and the non-active area NA are not limited to the lower substrate 111 and may be referred throughout the display device.

The active area AA is an area in which an image is displayed on the display device 100. The plurality of pixels PX are disposed in the active area AA. In addition, each of the pixels PX may include a display element and various driving elements for driving the display element. The various driving elements may mean at least one thin film transistor TFT and a capacitor, but are not limited thereto. In addition, each of the plurality of pixels PX may be connected to various lines. For example, each of the plurality of pixels PX may be connected to various lines such as gate lines, data lines, high potential voltage lines, low potential voltage lines, reference voltage lines and initialization voltage lines.

The non-active area NA is an area in which an image is not displayed. The non-active area NA may be an area adjacent to the active area AA. And, the non-active area NA may be an area that is adjacent to and surrounds the active area AA. However, the present disclosure is not limited thereto, and the non-active area NA corresponds to an area of the lower substrate 111 excluding the active area AA and may be changed and separated into various shapes. Components for driving the plurality of pixels PX disposed in the active area AA are disposed in the non-active area NA. The gate drivers GD and power supplies PS may be disposed in the non-active area NA. In addition, a plurality of pads that are connected to the gate drivers GD and the data drivers DD may be disposed in the non-active area NA, and each of the pads may be connected to each of the plurality of pixels PX in the active area AA.

On the lower substrate 111, the pattern layer 120 including a plurality of first plate patterns 121 and a plurality of first line patterns 122 that are disposed in the active area AA and a plurality of second plate patterns 123 and a plurality of second line patterns 124 that are disposed in the non-active area NA is disposed.

The plurality of first plate patterns 121 may be disposed in the active area AA of the lower substrate 111. The plurality of pixels PX may be formed on the plurality of first plate patterns 121. In addition, the plurality of second plate patterns 123 may be disposed in the non-active area NA of the lower substrate 111. In addition, the gate drivers GD and the power supplies PS are formed on the plurality of second plate patterns 123.

The plurality of first plate patterns 121 and the plurality of second plate patterns 123 as described above may be disposed in the form of islands that are spaced apart from each other. Each of the plurality of first plate patterns 121 and the plurality of second plate patterns 123 may be individually separated. Accordingly, the plurality of first plate patterns 121 and the plurality of second plate patterns 123 may be referred to as first island patterns and second island patterns, or first individual patterns and second individual patterns.

Specifically, the gate drivers GD may be mounted on the plurality of second plate patterns 123. The gate driver GD may be formed on the second plate pattern 123 in a gate in panel (GIP) method when various components on the first plate pattern 121 are manufactured. Accordingly, various circuit components constituting the gate drivers GD such as various transistors, capacitors, and lines may be disposed on the plurality of second plate patterns 123. However, the present disclosure is not limited thereto, and the gate driver GD may be mounted in a chip on film (COF) method.

In addition, the power supplies PS may be mounted on the plurality of second plate patterns 123. The power supply PS may be formed on the second plate pattern 123 with a plurality of power blocks that are patterned when various components on the first plate pattern 121 are manufactured. Accordingly, the power blocks disposed on different layers may be disposed on the second plate pattern 123. That is, a lower power block and an upper power block may be sequentially disposed on the second plate pattern 123. In addition, a low potential voltage may be applied to the lower power block, and a high potential voltage may be applied to the upper power block. Accordingly, the low potential voltage may be supplied to the plurality of pixels PX through the lower power block. In addition, the high potential voltage may be supplied to the plurality of pixels PX through the upper power block.

Referring to FIG. 1, sizes of the plurality of second plate patterns 123 may be greater than sizes of the plurality of first plate patterns 121. Specifically, the size of each of the plurality of second plate patterns 123 may be greater than the size of each of the plurality of first plate patterns 121. As described above, the gate driver GD may be disposed on each of the plurality of second plate patterns 123, and one stage of the gate driver GD may be disposed on each of the plurality of second plate patterns 123. Accordingly, since an area that is occupied by various circuit components constituting one stage of the gate driver GD is relatively greater than an area occupied by the pixels PX, the size of each of the plurality of second plate patterns 123 may be greater than the size of each of the first plate patterns 121.

In FIG. 1, the plurality of second plate patterns 123 are illustrated as being disposed on both sides in a first direction X in the non-active area NA, but the present disclosure is not limited thereto, and the plurality of second plate patterns 123 may be disposed in any area of the non-active area NA. In addition, although the plurality of first plate patterns 121 and the plurality of second plate patterns 123 are shown in a quadrangular shape, the present disclosure is not limited thereto, and the plurality of first plate patterns 121 and the plurality of second plate patterns 123 are changeable in various forms.

Referring to FIGS. 1 and 3, the pattern layer 120 may further include the plurality of first line patterns 122 disposed in the active area AA and the plurality of second line patterns 124 disposed in the non-active area NA.

The plurality of first line patterns 122 are patterns that are disposed in the active area AA and connect the first plate patterns 121 adjacent to each other, and may be referred to as first line patterns. That is, the plurality of first line patterns 122 are disposed between the plurality of first plate patterns 121.

The plurality of second line patterns 124 may be patterns that are disposed in the non-active area NA and connect the first plate patterns 121 and the second plate patterns 123 adjacent to each other or the plurality of second plate patterns 123 adjacent to each other. Accordingly, the plurality of second line patterns 124 may be referred to as second line patterns. And, the plurality of second line patterns 124 may be disposed between the first plate patterns 121 and the second plate patterns 123 that are adjacent to each other, and disposed between the plurality of second plate patterns 123 that are adjacent to each other.

Referring to FIG. 1, the plurality of first line patterns 122 and the plurality of second line patterns 124 have a wavy shape. For example, the plurality of first line patterns 122 and the plurality of second line patterns 124 may have a sine wave shape. However, the shapes of the plurality of first line patterns 122 and the plurality of second line patterns 124 are not limited thereto. For example, the plurality of first line patterns 122 and the plurality of second line patterns 124 may extend in a zigzag manner. Alternatively, the plurality of first line patterns 122 and the plurality of the second line patterns 124 may have various shapes, such as shapes in which a plurality of rhombus-shaped substrates are extended by being connected at vertices thereof. In addition, the numbers and shapes of the plurality of first line patterns 122 and the second line patterns 124 illustrated in FIG. 1 are example, and the numbers and shapes of the plurality of first line patterns 122 and the second line patterns 124 may be variously changed according to design.

In addition, the plurality of first plate patterns 121, the plurality of first line patterns 122, the plurality of second plate patterns 123, and the plurality of second line patterns 124 are rigid patterns. That is, the plurality of first plate patterns 121, the plurality of first line patterns 122, the plurality of second plate patterns 123, and the plurality of second line patterns 124 may be rigid compared to the lower substrate 111 and the upper substrate 112. Accordingly, moduli of elasticity of the plurality of first plate patterns 121, the plurality of first line patterns 122, the plurality of second plate patterns 123, and the plurality of second line patterns 124 may be higher than a modulus of elasticity of the lower substrate 111. The modulus of elasticity is a parameter representing a rate of deformation against a stress applied to the substrate. When the modulus of elasticity is relatively high, hardness may be relatively high. Accordingly, the plurality of first plate patterns 121, the plurality of first line patterns 122, the plurality of second plate patterns 123, and the plurality of second line patterns 124 may be referred to as a plurality of first rigid patterns, a plurality of second rigid patterns, a plurality of third rigid patterns, and a plurality of fourth rigid patterns, respectively. The moduli of elasticity of the plurality of first plate patterns 121, the plurality of first line patterns 122, the plurality of second plate patterns 123, and the plurality of second line patterns 124 may be 1000 times higher than the moduli of elasticity of the lower substrate 111 and the upper substrate 112, but the present disclosure is not limited thereto.

The plurality of first plate patterns 121, the plurality of first line patterns 122, the plurality of second plate patterns 123, and the plurality of second line patterns 124 that are a plurality of rigid substrates may be formed of a plastic material having flexibility that is lower than that of the lower substrate 111 and the upper substrate 112. For example, the plurality of first plate patterns 121, the plurality of first line patterns 122, the plurality of second plate patterns 123, and the plurality of second line patterns 124 may be formed of polyimide (PI), polyacrylate, polyacetate or the like. In this case, the plurality of first plate patterns 121, the plurality of first line patterns 122, the plurality of second plate patterns 123, and the plurality of second line patterns 124 may be formed of the same material, but they are not limited thereto and may be formed of different materials. When the plurality of first plate patterns 121, the plurality of first line patterns 122, the plurality of second plate patterns 123, and the plurality of second line patterns 124 are formed of the same material, they may be integrally formed.

In some embodiments, the lower substrate 111 may be defined as including a plurality of first lower patterns and a second lower pattern. The plurality of first lower patterns may be areas of the lower substrate 111 that overlap the plurality of first plate patterns 121 and the plurality of second plate patterns 123. The second lower pattern may be an area that does not overlap the plurality of first plate patterns 121 and the plurality of second plate patterns 123.

Also, the upper substrate 112 may be defined as including a plurality of first upper patterns and a second upper pattern. The plurality of first upper patterns may be areas of the upper substrate 112 that overlap the plurality of first plate patterns 121 and the plurality of second plate patterns 123. The second upper pattern may be an area that does not overlap the plurality of first plate patterns 121 and the plurality of second plate patterns 123.

In this case, moduli of elasticity of the plurality of first lower patterns and first upper patterns may be higher than moduli of elasticity of the second lower patterns and the second upper patterns. For example, the plurality of first lower patterns and the first upper patterns may be formed of the same material as the plurality of first plate patterns 121 and the plurality of second plate patterns 123, and the second lower pattern and the second upper pattern may be formed of a material having a modulus of elasticity lower than those of the plurality of first plate patterns 121 and the plurality of second plate patterns 123.

That is, the first lower pattern and the first upper pattern may be formed of polyimide (PI), polyacrylate, polyacetate, or the like. And, the second lower pattern and the second upper pattern may be formed of silicon rubber such as polydimethylsiloxane (PDMS) or elastomers such as polyurethane (PU) and polytetrafluoroethylene (PTFE).

### Non-Active Area Driving Element

The gate drivers GD are components which supply a gate voltage to the plurality of pixels PX disposed in the active area AA. The gate drivers GD include a plurality of stages formed on the plurality of second plate patterns 123 and respective stages of the gate drivers GD may be electrically connected to each other through a plurality of gate connection lines. Accordingly, a gate voltage output from any one of stages may be transmitted to another stage. Further, the respective stages may sequentially supply the gate voltage to the plurality of pixels PX connected to the respective stages.

The power supplies PS may be connected to the gate drivers GD and supply a gate driving voltage and a gate clock voltage. Further, the power supplies PS may be connected to the plurality of pixels PX and supply a pixel driving voltage to each of the plurality of pixels PX. The power supplies PS may also be formed on the plurality of second plate patterns 123. That is, the power supplies PS may be formed on the plurality of second plate patterns 123 to be adjacent to the gate drivers GD. Further, each of the power supplies PS formed on the plurality of second plate patterns 123 may be electrically connected to the gate driver GD and the plurality of pixels PX. That is, the plurality of power supplies PS formed on the plurality of second plate patterns 123 may be connected by a gate power supply connection line and a pixel power supply connection line. Therefore, each of the plurality of power supplies PS may supply a gate driving voltage, a gate clock voltage, and a pixel driving voltage.

The printed circuit board PCB is a component which transmits signals and voltages for driving the display element from a control unit to the display element. Therefore, the printed circuit board PCB may also be referred to as a driving substrate. A control unit such as an IC chip or a circuit may be mounted on the printed circuit board PCB. Further, a memory, a processor or the like may be mounted on the printed circuit board PCB. Further, the printed circuit board PCB provided in the display device 100 may include a stretchable area and a non-stretchable area to secure stretchability. Also, on the non-stretchable area, an IC chip, a circuit, a memory, a processor and the like may be mounted, and in the stretchable area, lines electrically connected to the IC chip, the circuit, the memory and the processor may be disposed.

The data driver DD is a component which supplies a data voltage to the plurality of pixels PX disposed in the active area AA. The data driver DD may be configured in a form of an IC chip and thus, may also be referred to as a data integrated circuit D-IC. Further, the data driver DD may be mounted on the non-stretchable area of the printed circuit board PCB. That is, the data driver DD may be mounted on the printed circuit board PCB in a form of a chip on board (COB). Although in FIG. 1, it is illustrated that the data driver DD is mounted in a chip on board (COB) manner, the present disclosure is not limited thereto and the data driver DD may be mounted in a chip on film (COF), a chip on glass (COG), a tape carrier package (TCP) manner, or the like.

Also, although it is illustrated in FIG. 1 that one data driver DD is disposed to correspond to a line of the first plate patterns 121 disposed in the active area AA, the present disclosure is not limited thereto. That is, one data driver DD may be disposed to correspond to a plurality of columns of the first plate patterns 121.

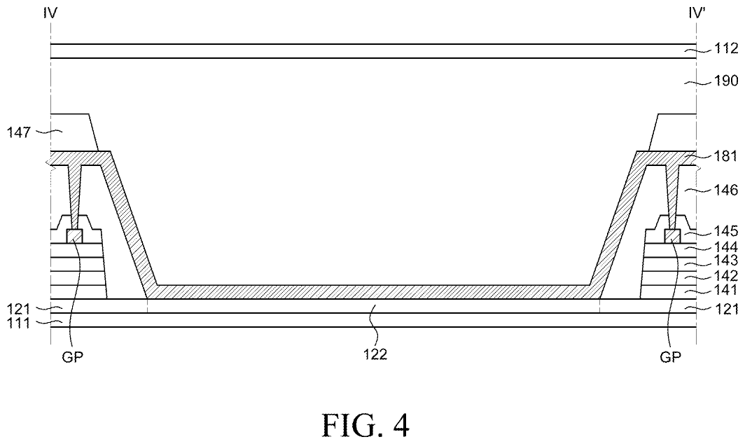

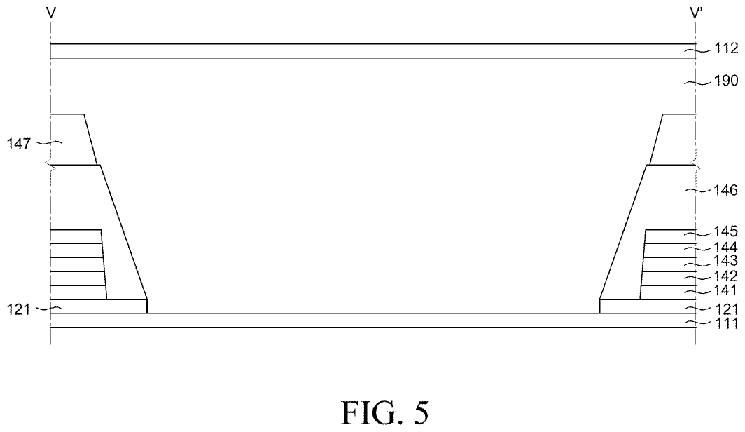

Hereinafter, FIGS. 4 and 5 are referred together for a more detailed description of the active area AA of the display device 100 according to an example embodiment of the present disclosure.

### Planar and Cross-Sectional Structures of Active Area

FIG. 4 is a cross-sectional view taken along cutting line IV-IV′ shown in FIG. 2.

FIG. 5 is a cross-sectional view taken along cutting line V-V′ shown in FIG. 2.

FIGS. 1 to 3 are referred together for convenience of description.

Referring to FIG. 1 and FIG. 2, the plurality of first plate patterns 121 are disposed on the lower substrate 111 in the active area AA. The plurality of first plate patterns 121 are disposed to be spaced apart from each other on the lower substrate 111. For example, the plurality of first plate patterns 121 may be disposed in a matrix form on the lower substrate 111 as shown in FIG. 1, but are not limited thereto.

Referring to FIG. 2 and FIG. 3, a pixel PX including a plurality of sub-pixels SPX is disposed on the first plate pattern 121. Also, each of the sub-pixels SPX may include an LED 170, which is a display element and a driving transistor 160 and a switching transistor 150 for driving the LED 170. However, the display element in the sub-pixel SPX is not limited to the LED and may be an organic light emitting diode. Further, the plurality of sub-pixels SPX may include a red sub-pixel, a green sub-pixel, and a blue sub-pixel, but are not limited thereto. Colors of the plurality of sub-pixels SPX may be variously changed as needed.

The plurality of sub-pixels SPX may be connected to a plurality of connection lines 181 and 182. That is, the plurality of sub-pixels SPX may be electrically connected to the first connection lines 181 extended in the first direction X. Also, the plurality of sub-pixels SPX may be electrically connected to the second connection lines 182 extended in a second direction Y.

Hereinafter, a cross-sectional structure of the active area AA will be described in detail with reference to FIG. 3.

Referring to FIG. 3, a plurality of inorganic insulating layers are disposed on the plurality of first plate patterns 121. For example, the plurality of inorganic insulating layers may include a buffer layer 141, a gate insulating layer 142, a first interlayer insulating layer 143, a second interlayer insulating layer 144, and a passivation layer 145. However, the present disclosure is not limited thereto. Various inorganic insulating layers may be further disposed on the plurality of first plate patterns 121. One or more of the buffer layer 141, the gate insulating layer 142, the first interlayer insulating layer 143, the second interlayer insulating layer 144, and the passivation layer 145 which are inorganic insulating layers may be omitted.

Specifically, the buffer layer 141 is disposed on the plurality of first plate patterns 121. The buffer layer 141 is formed on the plurality of first plate patterns 121 to protect various components of the display device 100 against permeation of moisture (H₂O), oxygen (O₂) or the like from the outside of the lower substrate 111 and the plurality of first plate patterns 121. The buffer layer 141 may be formed of an insulating material. For example, the buffer layer 141 may be formed as a single layer or multiple layers of silicon nitride (SiNx), silicon oxide (SiOx), silicon oxynitride (SiON), or the like. However, the buffer layer 141 may be omitted depending on a structure or characteristics of the display device 100.

In this case, the buffer layer 141 may be formed only in an area where the buffer layer 141 overlaps the plurality of first plate patterns 121 and the plurality of second plate patterns 123. As described above, the buffer layer 141 may be formed of an inorganic material. Thus, the buffer layer 141 may be easily damaged, such as easily cracked, while the display device 100 is stretched. Therefore, the buffer layer 141 may not be formed in areas between the plurality of first plate patterns 121 and the plurality of second plate patterns 123. The buffer layer 141 may be patterned into shapes of the plurality of first plate patterns 121 and the plurality of second plate patterns 123 and formed only on upper portions of the plurality of first plate patterns 121 and the plurality of second plate patterns 123. Accordingly, in the display device 100 according to an example embodiment of the present disclosure, the buffer layer 141 is formed only in the area where the buffer layer 141 overlaps the plurality of first plate patterns 121 and the plurality of second plate patterns 123 which are rigid substrates, so that damage to various components of the display device 100 may be prevented even when the display device 100 is deformed, such as bent or stretched.

Referring to FIG. 3, the switching transistor 150 including a gate electrode 151, an active layer 152, a source electrode 153 and a drain electrode 154, and the driving transistor 160 including a gate electrode 161, an active layer 162, a source electrode and a drain electrode 164 are formed on the buffer layer 141.

First, referring to FIG. 1, the active layer 152 of the switching transistor 150 and the active layer 162 of the driving transistor 160 are disposed on the buffer layer 141. For example, each of the active layer 152 of the switching transistor 150 and the active layer 162 of the driving transistor 160 may be formed of an oxide semiconductor. For example, the active layer 152 may be formed of indium-gallium-zinc oxide, indium-gallium oxide, or indium-zinc oxide. Alternatively, the active layer 152 of the switching transistor 150 and the active layer 162 of the driving transistor 160 may be formed of amorphous silicon (a-Si), polycrystalline silicon (poly-Si), an organic semiconductor or the like.

The gate insulating layer 142 is disposed on the active layer 152 of the switching transistor 150 and the active layer 162 of the driving transistor 160. The gate insulating layer 142 is configured to electrically insulate the gate electrode 151 of the switching transistor 150 from the active layer 152 of the switching transistor 150 and electrically insulate the gate electrode 161 of the driving transistor 160 from the active layer 162 of the driving transistor 160. Further, the gate insulating layer 142 may be formed of an insulating material. For example, the gate insulating layer 142 may be formed as a single layer of silicon nitride (SiNx) or silicon oxide (SiOx) or multiple layers of silicon nitride (SiNx) or silicon oxide (SiOx), but is not limited thereto.

The gate electrode 151 of the switching transistor 150 and the gate electrode 161 of the driving transistor 160 are disposed on the gate insulating layer 142. The gate electrode 151 of the switching transistor 150 and the gate electrode 161 of the driving transistor 160 are disposed to be spaced apart from each other on the gate insulating layer 142. Further, the gate electrode 151 of the switching transistor 150 overlaps the active layer 152 of the switching transistor 150, and the gate electrode 161 of the driving transistor 160 overlaps the active layer 162 of the driving transistor 160.

Each of the gate electrode 151 of the switching transistor 150 and the gate electrode 161 of the driving transistor 160 may be formed of any one of various metal materials, for example, any one of molybdenum (Mo), aluminum (Al), chromium (Cr), gold (Au), titanium (Ti), nickel (Ni), neodymium (Nd) and copper (Cu). Alternatively, each of the gate electrode 151 of the switching transistor 150 and the gate electrode 161 of the driving transistor 160 may be formed of an alloy of two or more of them, or a plurality of layer thereof, but is not limited thereto.

The first interlayer insulating layer 143 is disposed on the gate electrode 151 of the switching transistor 150 and the gate electrode 161 of the driving transistor 160. The first interlayer insulating layer 143 insulates the gate electrode 161 of the driving transistor 160 from an intermediate metal layer IM. The first interlayer insulating layer 143 may also be formed of an inorganic material like the buffer layer 141. For example, the first interlayer insulating layer 143 may be formed as a single layer of silicon nitride (SiNx) or silicon oxide (SiOx) or multiple layers of silicon nitride (SiNx) or silicon oxide (SiOx), but is not limited thereto.

The intermediate metal layer IM is disposed on the first interlayer insulating layer 143. Further, the intermediate metal layer IM overlaps the gate electrode 161 of the driving transistor 160. Thus, a storage capacitor is formed in an area where the intermediate metal layer IM overlaps the gate electrode 161 of the driving transistor 160. Specifically, the gate electrode 161 of the driving transistor 160, the first interlayer insulating layer 143 and the intermediate metal layer IM form the storage capacitor. However, a position of the intermediate metal layer IM is not limited thereto. The intermediate metal layer IM may overlap another electrode to form a storage capacitor in various ways.

The intermediate metal layer IM may be formed of any one of various metal materials, for example, any one of molybdenum (Mo), aluminum (Al), chromium (Cr), gold (Au), titanium (Ti), nickel (Ni), neodymium (Nd) and copper (Cu). Alternatively, the intermediate metal layer IM may be formed of an alloy of two or more of them, or a plurality of layer thereof, but is not limited thereto.

The second interlayer insulating layer 144 is disposed on the intermediate metal layer IM. The second interlayer insulating layer 144 insulates the gate electrode 151 of the switching transistor 150 from the source electrode 153 and the drain electrode 154 of the switching transistor 150. Also, the second interlayer insulating layer 144 insulates the intermediate metal layer IM from the source electrode and the drain electrode 164 of the driving transistor 160. The second interlayer insulating layer 144 may also be formed of an inorganic material like the buffer layer 141. For example, the first interlayer insulating layer 143 may be formed as a single layer of silicon nitride (SiNx) or silicon oxide (SiOx) or multiple layers of silicon nitride (SiNx) or silicon oxide (SiOx), but is not limited thereto.

The source electrode 153 and the drain electrode 154 of the switching transistor 150 are disposed on the second interlayer insulating layer 144. Also, the source electrode and the drain electrode 164 of the driving transistor 160 are disposed on the second interlayer insulating layer 144. The source electrode 153 and the drain electrode 154 of the switching transistor 150 are disposed to be spaced apart from each other on the same layer. Further, although FIG. 1 does not illustrate the source electrode of the driving transistor 160, the source electrode of the driving transistor 160 is also disposed to be spaced apart from the drain electrode 164 of the driving transistor 160 on the same layer. In the switching transistor 150, the source electrode 153 and the drain electrode 154 may be electrically connected to the active layer 152 to be in contact with the active layer 152. Also, in the driving transistor 160, the source electrode and the drain electrode 164 may be electrically connected to the active layer 162 to be in contact with the active layer 162. Further, the drain electrode 154 of the switching transistor 150 may be electrically connected to the gate electrode 161 of the driving transistor 160 to be in contact with the gate electrode 161 of the driving transistor 160 through a contact hole.

The source electrode 153 and the drain electrodes 154 and 164 may be formed of any one of various metal materials, for example, any one of molybdenum (Mo), aluminum (Al), chromium (Cr), gold (Au), titanium (Ti), nickel (Ni), neodymium (Nd) and copper (Cu). Alternatively, the source electrode 153 and the drain electrodes 154 and 164 may be formed of an alloy of two or more of them, or a plurality of layer thereof, but are not limited thereto.

Further, in the present disclosure, the driving transistor 160 has been described as having a coplanar structure, but various types of transistors having a staggered structure or the like may also be used. Also, in the present specification, the transistor may be formed not only in a top gate structure but also in a bottom gate structure.

A gate pad GP and a data pad DP may be disposed on the second interlayer insulating layer 144.

Specifically, referring to FIG. 4, the gate pad GP serves to transfer a gate voltage to the plurality of sub-pixels SPX. The gate pad GP is connected to the first connection line 181 through a contact hole. In addition, the gate voltage supplied from the first connection line 181 may be transferred from the gate pad GP to the gate electrode 151 of the switching transistor 150 through a line formed on the first plate pattern 121.

In addition, referring to FIG. 2, the data pad DP serves to transfer a data voltage to the plurality of sub-pixels SPX. The data pad DP is connected to the second connection line 182 through a contact hole. In addition, the data voltage supplied from the second connection line 182 may be transferred from the data pad DP to the source electrode 153 of the switching transistor 150 through a line formed on the first plate pattern 121.

And, referring to FIG. 3, a voltage pad VP is a pad for transferring a low potential voltage to the plurality of sub-pixels SPX. The voltage pad VP is connected to the first connection line 181 through a contact hole. In addition, the low potential voltage supplied from the first connection line 181 may be transferred from the voltage pad VP to an n-electrode 174 of the LED 170 through a second connection pad CNT2 formed on the first plate pattern 121.

The voltage pad VP, the gate pad GP, and the data pad DP may be formed of the same material as the source electrode 153 and the drain electrodes 154 and 164, but are not limited thereto.

Referring to FIG. 1, the passivation layer 145 is formed on the switching transistor 150 and the driving transistor 160. The passivation layer 145 covers the switching transistor 150 and the driving transistor 160 to protect the switching transistor 150 and the driving transistor 160 against permeation of moisture, oxygen, and the like. The passivation layer 145 may be formed of an inorganic material and formed as a single layer or a plurality of layers, but is not limited thereto.

Also, the gate insulating layer 142, the first interlayer insulating layer 143, the second interlayer insulating layer 144 and the passivation layer 145 may be patterned and formed only in an area where they overlap the plurality of first plate patterns 121. The gate insulating layer 142, the first interlayer insulating layer 143, the second interlayer insulating layer 144 and the passivation layer 145 may also be formed of an inorganic material like the buffer layer 141. Thus, the gate insulating layer 142, the first interlayer insulating layer 143, the second interlayer insulating layer 144 and the passivation layer 145 may be easily damaged, such as easily cracked, while the display device 100 is stretched. Therefore, the gate insulating layer 142, the first interlayer insulating layer 143, the second interlayer insulating layer 144 and the passivation layer 145 may not be formed in areas between the plurality of first plate patterns 121 and may be patterned into the shapes of the plurality of first plate patterns 121 and formed only on upper portions of the plurality of first plate patterns 121.

A planarization layer 146 is formed on the passivation layer 145. The planarization layer 146 serves to flatten upper portions of the switching transistor 150 and the driving transistor 160. The planarization layer 146 may be formed as a single layer or a plurality of layers and may be formed of an organic material. Thus, the planarization layer 146 may also be referred to as an organic insulating layer. For example, the planarization layer 146 may be formed of an acrylic-based organic material, but is not limited thereto.

Referring to FIG. 3, the planarization layer 146 may be disposed on the plurality of first plate patterns 121 so as to cover upper surfaces and side surfaces of the buffer layer 141, the gate insulating layer 142, the first interlayer insulating layer 143, the second interlayer insulating layer 144 and the passivation layer 145. In addition, the planarization layer 146 surrounds the buffer layer 141, the gate insulating layer 142, the first interlayer insulating layer 143, the second interlayer insulating layer 144 and the passivation layer 145 together with the plurality of first plate patterns 121. Specifically, the planarization layer 146 may be disposed to cover an upper surface and a side surface of the passivation layer 145, a side surface of the first interlayer insulating layer 143, a side surface of the second interlayer insulating layer 144, a side surface of the gate insulating layer 142, a side surface of the buffer layer 141 and a part of upper surfaces of the plurality of first plate patterns 121. Thus, the planarization layer 146 may compensate for steps between the side surfaces of the buffer layer 141, the gate insulating layer 142, the first interlayer insulating layer 143, the second interlayer insulating layer 144, and the passivation layer 145, and may enhance adhesion strength between the planarization layer 146 and the connection lines 181 and 182 disposed on side surfaces of the planarization layer 146.

Referring to FIG. 3, an incline angle of the side surface of the planarization layer 146 may be less than those of the side surfaces of the buffer layer 141, the gate insulating layer 142, the first interlayer insulating layer 143, the second interlayer insulating layer 144 and the passivation layer 145. For example, the side surface of the planarization layer 146 may have a gentle incline than the side surface of the passivation layer 145, the side surface of the first interlayer insulating layer 143, the side surface of the second interlayer insulating layer 144, the side surface of the gate insulating layer 142 and the side surface of the buffer layer 141. Thus, the connection lines 181 and 182 in contact with the side surfaces of the planarization layer 146 are disposed to have a gentle incline. Therefore, when the display device is stretched, a stress generated in the connection lines 181 and 182 may be reduced. Also, it is possible to suppress cracks in the connection lines 181 and 182 or peeling of the connection lines 181 and 182 from the side surface of the planarization layer 146.

Referring to FIGS. 2 to 4, the connection lines 181 and 182 refer to lines that electrically connect the pads disposed on the plurality of first plate patterns 121. The plurality of connection lines 181 and 182 are disposed on the plurality of first line patterns 122. In this manner, the plurality of the connection lines 181 and 182 that are disposed on the first plate patterns 121 may also extend on the plurality of first plate patterns 121 to be electrically connected to the gate pad GP and the data pad DP on the plurality of first plate patterns 121. Also, referring to FIG. 1, the first line pattern 122 is not disposed in an area between the plurality of first plate patterns 121, in which the connection lines 181 and 182 are not disposed.

The connection lines 181 and 182 include the first connection lines 181 and the second connection lines 182. The first connection lines 181 and the second connection lines 182 are disposed between the plurality of first plate patterns 121. Specifically, the first connection lines 181 refer to lines extended in an X-axis direction X between the plurality of first plate patterns 121 among the connection lines 181 and 182. The second connection lines 182 refer to lines extended in a Y-axis direction between the plurality of first plate patterns 121 among the connection lines 181 and 182.

The connection lines 181 and 182 may be formed of a metal material such as copper (Cu), aluminum (Al), titanium (Ti) or molybdenum (Mo), or the connection lines 181 and 182 may have a laminated structure of metal materials such as copper/molybdenum-titanium (Cu/MoTi), titanium/aluminum/titanium (Ti/Al/Ti), or the like, but are not limited thereto.

In a display panel of a general display device, various lines such as a plurality of gate lines and a plurality of data lines are extended in straight lines and are disposed between a plurality of sub-pixels, and the plurality of sub-pixels are connected to a single signal line. Therefore, in the display panel of the general display device, various lines such as a gate line, a data line, a high potential voltage line and a reference voltage line are continuously extended on a substrate from one side to the other side of the display panel of an organic light emitting display device.

Unlike this, in the display device 100 according to an example embodiment of the present disclosure, various lines such as a gate line, a data line, a high potential voltage line, a reference voltage line, an initialization voltage line and the like which are formed in straight lines and considered to be used in a display panel of a general organic light emitting display device, are disposed only on the plurality of first plate patterns 121 and the plurality of second plate patterns 123. In the display device 100 according to an example embodiment of the present disclosure, lines formed in straight lines are disposed only on the plurality of first plate patterns 121 and the plurality of second plate patterns 123.

In the display device 100 according to an example embodiment of the present disclosure, the pads on two adjacent first plate patterns 121 may be connected by the connection lines 181 and 182. Accordingly, the connection lines 181 and 182 electrically connect the gate pads GP or the data pads DP on the two adjacent first plate patterns 121. Therefore, the display device 100 according to an example embodiment of the present disclosure may include the plurality of connection lines 181 and 182 to electrically connect various lines, such as a gate line, a data line, a high potential voltage line and a reference voltage line, between the plurality of first plate patterns 121. For example, gate lines may be disposed on the plurality of first plate patterns 121 disposed adjacent to each other in the first direction X. Also, the gate pads GP may be disposed on both ends of the gate lines. In this case, a plurality of gate pads GP on the plurality of first plate patterns 121 disposed adjacent to each other in the first direction X may be connected to each other by the first connection lines 181 serving as the gate lines. Therefore, the gate lines disposed on the plurality of first plate patterns 121 and the first connection lines 181 disposed on the second plate patterns 123 may serve as single gate lines. The gate lines described above may be referred to as scan signal lines. Further, lines, such as an emission signal line, a low potential voltage line and a high potential voltage line which are extended in the first direction X among all of various lines that may be included in the display device 100, may also be electrically connected by the first connection lines 181 as described above.

Referring to FIG. 2 and FIG. 4, the first connection lines 181 may connect the gate pads GP on two first plate patterns 121 that are disposed side by side among the gate pads GP on the plurality of first plate patterns 121 disposed adjacent to each other in the first direction X. The first connection line 181 may serve as a gate line, an emission signal line, a high potential voltage line, or a low potential voltage line, but is not limited thereto. For example, the first connection line 181 may serve as a gate line, and may electrically connect the gate pads GP on the two first plate patterns 121 that are disposed side by side in the first direction X. Accordingly, as described above, the gate pads GP on the plurality of first plate patterns 121 disposed in the first direction X may be connected by the first connection lines 181 serving as the gate lines. A single gate voltage may be transferred to the gate pads GP.

Further, referring to FIG. 2, the second connection lines 182 may connect the data pads DP on two first plate patterns 121 that are disposed side by side among the data pads DP on the plurality of first plate patterns 121 disposed adjacent to each other in the second direction Y. The second connection line 182 may serve as a data line, a high potential voltage line, a low potential voltage line or a reference voltage line, but is not limited thereto. For example, the second connection line 182 may serve as a data line, and may electrically connect the data pads DP on the two first plate patterns 121 that are disposed side by side in the second direction Y. Accordingly, as described above, internal lines on the plurality of first plate patterns 121 disposed in the second direction Y may be connected by a plurality of second connection lines 182 serving as the data lines. A single data voltage may be transferred thereto.

As shown in FIG. 4, the first connection line 181 may be in contact with an upper surface and the side surface of the planarization layer 146 disposed on the first plate pattern 121 and may be extended to an upper surface of the first line pattern 122. In addition, as illustrated in FIG. 1, the second connection line 182 may be disposed to be in contact with the upper surface and the side surface of the planarization layer 146 disposed on the first plate pattern 121, and may be extended to the upper surface of the first line pattern 122.

However, as shown in FIG. 5, there is no need for a rigid pattern to be disposed in an area where the first connection line 181 and the second connection line 182 are not disposed. Thus, the first line pattern, which is a rigid pattern, is not disposed under the first connection line 181 and the second connection line 182.

Meanwhile, referring to FIG. 3, a bank 147 is formed on a first connection pad CNT1, the connection lines 181 and 182 and the planarization layer 146. The bank 147 is a component to distinguish adjacent sub-pixels SPX. The bank 147 is disposed to cover at least a part of the pad PD, the connection lines 181 and 182 and the planarization layer 146. The bank 147 may be formed of an insulating material. Further, the bank 147 may contain a black material. Since the bank 147 contains a black material, the bank 147 serves to hide lines which are visible through the active area AA. The bank 147 may be formed of, for example, a transparent carbon-based mixture. Specifically, the bank 147 may contain carbon black, but is not limited thereto. The bank 147 may also be formed of a transparent insulating material. Also, although a height of the bank 147 is shown to be lower than a height of the LED 170 in FIG. 1, the height of the bank 147 is not limited thereto, and the height of the bank 147 may be the same as the height of the LED 170.

Referring to FIG. 3, the LED 170 is disposed on the first connection pad CNT1 and a second connection pad CNT2. The LED 170 includes an n-type layer 171, an active layer 172, a p-type layer 173, an n-electrode 174 and a p-electrode 175. The LED 170 of the display device 100 according to an example embodiment of the present disclosure has a flip-chip structure in which the n-electrode 174 and the p-electrode 175 are formed on one surface thereof.

The n-type layer 171 may be formed by injecting n-type impurities into gallium nitride (GaN) having excellent crystallinity. The n-type layer 171 may be disposed on a separate base substrate which is formed of a light emitting material.

The active layer 172 is disposed on the n-type layer 171. The active layer 172 is a light emitting layer that emits light in the LED 170 and may be formed of a nitride semiconductor, for example, indium gallium nitride (InGaN). The p-type layer 173 is disposed on the active layer 172. The p-type layer 173 may be formed by injecting p-type impurities into gallium nitride (GaN).

As described above, the LED 170 according to an example embodiment of the present disclosure is manufactured by sequentially laminating the n-type layer 171, the active layer 172, and the p-type layer 173, and then, etching a predetermined area of the layers to thereby form the n-electrode 174 and the p-electrode 175. In this case, the predetermined area is a space to separate the n-electrode 174 and the p-electrode 175 from each other and is etched to expose a part of the n-type layer 171. In other words, a surface of the LED 170 on which the n-electrode 174 and the p-electrode 175 are to be disposed may not be flat and may have different levels of height.

In this manner, the n-electrode 174 is disposed in the etched area, and the n-electrode 174 may be formed of a conductive material. In addition, the p-electrode 175 is disposed in a non-etched area, and the p-electrode 175 may also be formed of a conductive material. For example, the n-electrode 174 is disposed on the n-type layer 171 exposed by an etching process, and the p-electrode 175 is disposed on the p-type layer 173. The p-electrode 175 may be formed of the same material as the n-electrode 174.

An adhesive layer AD is disposed on upper surfaces of the first connection pad CNT1 and the second connection pad CNT2 and between the first connection pad CNT1 and the second connection pad CNT2. Thus, the LED 170 may be bonded onto the first connection pad CNT1 and the second connection pad CNT2. In this case, the n-electrode 174 may be disposed on the second connection pad CNT2 and the p-electrode 175 may be disposed on the first connection pad CNT1.

The adhesive layer AD may be a conductive adhesive layer formed by dispersing conductive balls in an insulating base member. Thus, when heat or pressure is applied to the adhesive layer AD, the conductive balls are electrically connected to have conductive properties in a portion of the adhesive layer AD to which heat or pressure is applied. Also, an area of the adhesive layer AD to which pressure is not applied may have insulating properties. For example, the n-electrode 174 is electrically connected to the second connection pad CNT2 through the adhesive layer AD, and the p-electrode 175 is electrically connected to the first connection pad CNT1 through the adhesive layer AD. After applying the adhesive layer AD to upper surfaces of the second connection pad CNT2 and the first connection pad CNT1 by an inkjet method or the like, the LED 170 may be transferred onto the adhesive layer AD. Then, the LED 170 may be pressed and heated to thereby electrically connect the first connection pad CNT1 to the p-electrode 175 and the second connection pad CNT2 to the n-electrode 174. However, other portions of the adhesive layer AD excluding a portion of the adhesive layer AD disposed between the n-electrode 174 and the second connection pad CNT2 and a portion of the adhesive layer AD disposed between the p-electrode 175 and the first connection pad CNT1 have insulating properties. Meanwhile, the adhesive layer AD may be separately disposed on each of the first connection pad CNT1 and the second connection pad CNT2.

Further, the first connection pad CNT1 is electrically connected to the drain electrode 164 of the driving transistor 160 and receives a driving voltage for driving the LED 170 from the driving transistor 160. Although FIG. 3 illustrates that the first connection pad CNT1 and the drain electrode 164 of the driving transistor 160 are indirectly connected to each other without directly contacting them, the present disclosure is not limited thereto, and the first connection pad CNT1 and the drain electrode 164 of the driving transistor 160 may be in direct contact. In addition, a low potential driving voltage for driving the LED 170 is applied to the second connection pad CNT2. Accordingly, when the display device 100 is turned on, different voltage levels that are applied to the first connection pad CNT1 and the second connection pad CNT2 are respectively transferred to the n-electrode 174 and the p-electrode 175, so that the LED 170 emits light.

The upper substrate 112 serves to support various components disposed under the upper substrate 112. Specifically, the upper substrate 112 may be formed by coating and hardening a material for forming the upper substrate 112 on the lower substrate 111 and the first plate patterns 121. The upper substrate 112 may be disposed to be in contact with the lower substrate 111, the first plate patterns 121, the first line pattern 122 and the connection lines 181 and 182.

The upper substrate 112 may be formed of the same material as the lower substrate 111. For example, the upper substrate 112 may be formed of silicone rubber such as polydimethylsiloxane (PDMS) or elastomers such as polyurethane (PU), and polytetrafluoroethylene (PTFE). Thus, the upper substrate 112 may have flexibility. However, the materials of the upper substrate 112 are not limited thereto.

Meanwhile, although not shown in FIG. 3, a polarizing layer may also be disposed on the upper substrate 112. The polarizing layer polarizes light incident from the outside of the display device and reduces reflection of external light. Further, instead of the polarizing layer, other optical films or the like may be disposed on the upper substrate 112.

In addition, the filling layer 190 that is disposed on an entire surface of the lower substrate 111 and fills a gap between components disposed on the upper substrate 112 and the lower substrate 111 may be disposed. The filling layer 190 may be formed of a curable adhesive. Specifically, a material for forming the filling layer 190 is coated on the entire surface of the lower substrate 111 and then cured, so that the filling layer 190 may be disposed between components disposed on the upper substrate 112 and the lower substrate 111. For example, the filling layer 190 may be an optically clear adhesive (OCA), and may include an acrylic adhesive, a silicone adhesive, and a urethane adhesive.

### Circuit Structure and Driving Method of Active Area

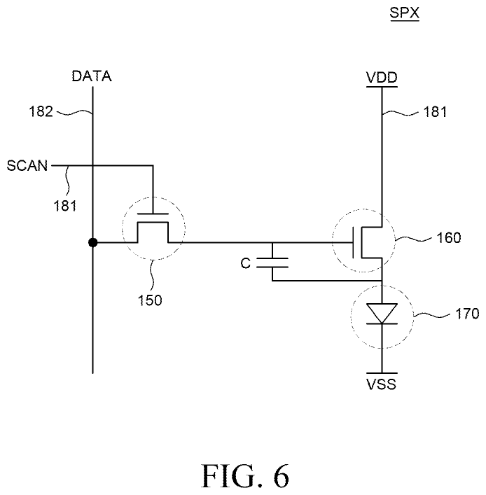

FIG. 6 is a circuit diagram of a sub-pixel of the display device according to an example embodiment of the present disclosure.

Hereinafter, for convenience of explanation, a structure and operations of the sub-pixel SPX of the display device according to an example embodiment of the present disclosure in a case in which the sub-pixel SPX is a 2T (Transistor) 1C (Capacitor) pixel circuit will be described, but the present disclosure is not limited thereto.

Referring to FIGS. 3 and 6, the sub-pixel SPX of the display device according to an example embodiment of the present disclosure may be configured to include the switching transistor 150, the driving transistor 160, a storage capacitor C, and the LED 170.

The switching transistor 150 applies a data signal DATA that is supplied through the second connection line 182 to the driving transistor 160 and the storage capacitor C according to a gate signal SCAN that is supplied through the first connection line 181.

In addition, the gate electrode 151 of the switching transistor 150 is electrically connected to the first connection line 181, the source electrode 153 of the switching transistor 150 is connected to the second connection line 182, and the drain electrode 154 of the switching transistor 150 is connected to the gate electrode 161 of the driving transistor 160.

The driving transistor 160 may operate so that a driving current according to the data voltage DATA and a high potential power VDD supplied through the first connection line 181 can flow in response to the data voltage DATA stored in the storage capacitor C.

In addition, the gate electrode 161 of the driving transistor 160 is electrically connected to the drain electrode 154 of the switching transistor 150, the source electrode of the driving transistor 160 is connected to the first connection line 181, and the drain electrode 164 of the driving transistor 160 is connected to the LED 170.

The LED 170 may operate to emit light according to the driving current that is formed by the driving transistor 160. And, as described above, the n-electrode 174 of the LED 170 may be connected to the first connection line 181 and receive a low potential power VS S, and the p-electrode 175 of the LED 170 may be connected to the drain electrode 164 of the transistor 160 and receive a driving voltage corresponding to the driving current.

The sub-pixel SPX of the display device according to an example embodiment of the present disclosure is configured to have a 2T1C structure including the switching transistor 150, the driving transistor 160, the storage capacitor C, and the LED 170, but in a case in which a compensation circuit is added, it may be configured to have various structures such as 3T1C, 4T2C, 5T2C, 6T1C, 6T2C, 7T1C, 7T2C, and the like.

As described above, the display device according to an example embodiment of the present disclosure may include a plurality of sub-pixels on a first substrate that is a rigid substrate, and each of the plurality of sub-pixels SPX may be configured to include a switching transistor, a driving transistor, a storage capacitor and an LED.

Accordingly, the display device according to an example embodiment of the present disclosure can be stretched by a lower substrate and also has a pixel circuit of a 2T1C structure on each first substrate, so that it can emit light depending on a data voltage in accordance with each gate timing.

### Shape of Connection Lines

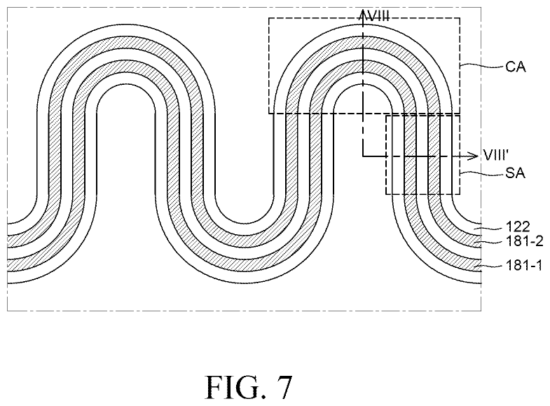

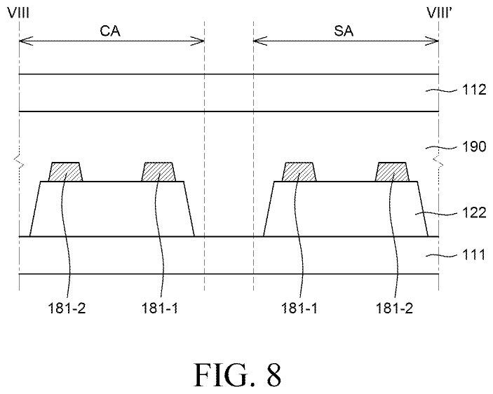

FIG. 7 is a view illustrating connection lines of the display device according to an example embodiment of the present disclosure. FIG. 8 is a cross-sectional view taken along line VIII-VIII′ of FIG. 7.

The first connection line and the second connection line shown in FIGS. 7 and 8 are different only in terms of their arrangement directions and have substantially the same shape. Therefore, the first connection line will be described in detail with reference to FIGS. 7 and 8.

Referring to FIG. 7, each of the plurality of first line patterns 122 and a plurality of first connection lines 181-1 and 181-2 has a wavy shape. As described above, each of the plurality of first line patterns 122 and the plurality of first connection lines 181-1 and 181-2 may have various shapes such as a sine wave shape, a zigzag shape and the like.

Accordingly, each of the plurality of first line patterns 122 and the plurality of first connection lines 181-1 and 181-2 may include a straight area SA and a curved area CA. That is, an area in which each of the plurality of first line patterns 122 and the plurality of first connection lines 181-1 and 181-2 are disposed may be divided into a straight area SA and a curved area CA. In the straight area SA, each of the plurality of first line patterns 122 and the plurality of first connection lines 181-1 and 181-2 may extend in a straight line without being bent. In addition, in the curved area CA, each of the plurality of first line patterns 122 and the plurality of first connection lines 181-1 and 181-2 does not extend in a straight line, but may be bent with a predetermined curvature. However, in FIG. 7, each of the plurality of first line patterns 122 and the plurality of first connection lines 181-1 and 181-2 is shown to be bent while maintaining a constant curvature in the curved area CA. As illustrated, the plurality of connection lines 181-1 and 181-2 (or plurality of line patterns 122) have a first curvature that is constant within the curved area CA. The straight area SA is contiguous to the curved area CA. The straight area SA has a second curvature that is also constant within the straight area SA. In the straight area SA, the second curvature is zero as a curvature of a straight line is zero. The first curvature in the curved area CA, on the other hand, has a curvature that is greater than zero. A curvature may be determined based on the following formula R=1/K, where R is the radius of curvature and K is the curvature.

However, the present disclosure is not limited thereto, and each of the plurality of first line patterns 122 and the plurality of first connection lines 181-1 and 181-2 may be bent while maintaining a variable curvature or may be curved at a certain angle in the curved area CA according to necessity in design.

Referring to FIGS. 7 and 8, a plurality of connection lines may be disposed on one first line pattern 122. Specifically, a 1-1 connection line 181-1 and a 1-2 connection line 181-2 may be disposed on one first line pattern 122 in each of the straight area SA and the curved area CA. In other words, on one first line pattern 122, one side connection line corresponding to the 1-1 connection line 181-1 and the other side connection line corresponding to the 1-2 connection line 181-2 may be disposed. The 1-1 connection line 181-1 and the 1-2 connection line 181-2 that are disposed on one first line pattern 122 may be disposed at a predetermined interval and with the same shape.

In addition, the 1-1 connection line 181-1 and the 1-2 connection line 181-2 disposed on one first line pattern 122 may transmit different voltages. For example, if the 1-1 connection line 181-1 serves as a gate line transmitting a gate voltage, the 1-2 connection line 181-2 may be a high potential voltage line transmitting a high potential voltage. However, functions of the 1-1 connection line 181-1 and the 1-2 connection line 181-2 disposed on one first line pattern 122 are not limited thereto, and can be variously changed according to necessity in design.

In FIG. 7, the first connection line is described in detail, and the second connection line is not specifically illustrated. However, the second connection line may also include a 2-1 connection line and a 2-2 connection line disposed on one first line pattern in the same manner as the first connection line. In addition, the 2-1 connection line and the 2-2 connection line disposed on one first line pattern may be disposed at a predetermined interval and with the same shape.

That is, in the display device according to an example embodiment of the present disclosure, the plurality of connection lines 181-1 and 181-2 having the same shape may be disposed on one first line pattern 122.

Unlike this, in a conventional display device, only one connection line was disposed on one line pattern. Accordingly, when the conventional display device was stretched, stretching stress applied to a plurality of connection lines in a curved area was measured as a maximum of 11.36 MPa. As a result, in the conventional display device, the possibility of occurring cracks in the plurality of connection lines is high, and thus there is a defect of disconnection.

Unlike this, in the display device according to an example embodiment of the present disclosure, a plurality of connection lines are disposed on one line pattern, so that the plurality of connection lines disposed on one line pattern distributes stretching stress that is applied in a curved area. That is, stretching stress applied to each of the plurality of connection lines disposed on one line pattern may be reduced. Thus, when the display device according to an example embodiment of the present disclosure is stretched, the stretching stress applied to each of the plurality of connection lines was measured as a maximum of 7.5 MPa. That is, the stretching stress applied to each of the plurality of connection lines was reduced to a maximum of 66% at the same stretching rate. Accordingly, in the display device according to an example embodiment of the present disclosure, a defect of disconnection of the connection lines may be solved. This can improve stretching reliability of the display device.

In addition, in the conventional display device, only one connection line is disposed on one line pattern, and the number of line patterns that is equal to the number of connection lines is required to connect adjacent plate patterns. Accordingly, in the conventional display device, a ratio of a length of the connection line in a stretching direction before stretching to a length of the connection line in the stretching direction after stretching was measured as 2.16 times.

However, in the display device according to an example embodiment of the present disclosure, the number of line patterns connecting adjacent plate patterns may be reduced by disposing a plurality of connection lines on one line pattern. Accordingly, a length of a straight area of one line pattern may be increased. Accordingly, in the display device according to an example embodiment of the present disclosure, a ratio of a length of the connection line in a stretching direction before stretching to a length of the connection line in the stretching direction after stretching was measured was measured as 2.84 times. That is, it was confirmed that the stretching rate was improved in the display device according to an example embodiment of the present disclosure.

Hereinafter, a display device according to another example embodiment of the present disclosure will be described. Since there are differences between the display device according to another example embodiment of the present disclosure and the display device according to an example embodiment of the present disclosure only in terms of a buffer hole, this will be described in detail. In addition, in the display device according to another example embodiment of the present disclosure and the display device according to an example embodiment of the present disclosure, the same reference numerals are used for the same components, and a detailed description thereof will be omitted.

### Another Example Embodiment of the Present Disclosure

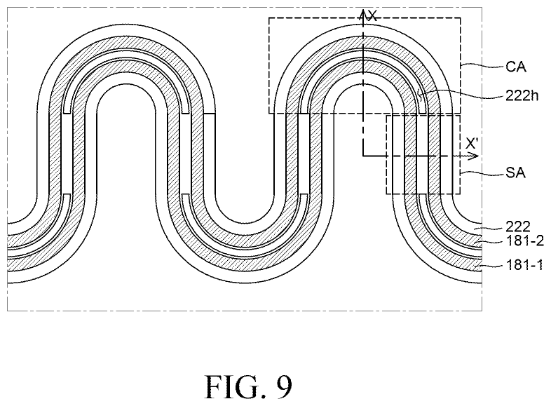

FIG. 9 is a view illustrating connection lines of a display device according to another example embodiment of the present disclosure.

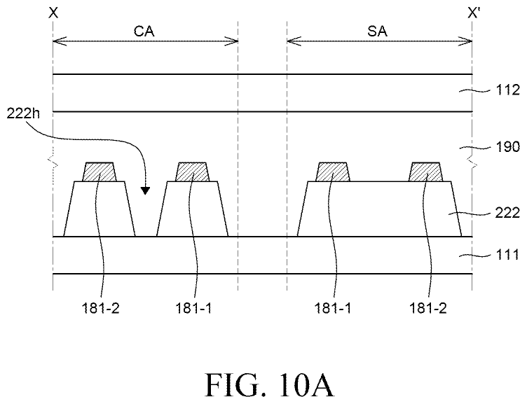

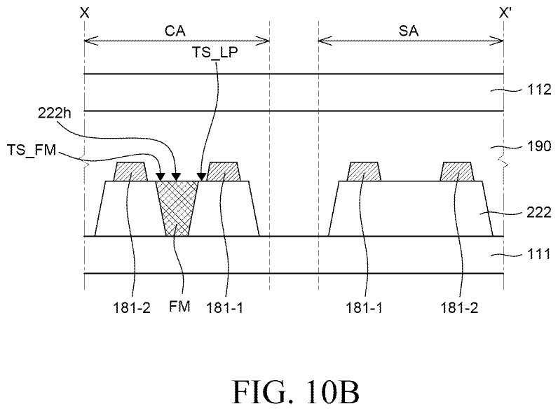

FIGS. 10A and 10B are cross-sectional views taken along line X-X′ of FIG. 9.

The first connection line and the second connection line shown in FIG. 9 and FIGS. 10A and 10B are different only in terms of their arrangement directions and have substantially the same shape. Therefore, the first connection line will be described in detail with reference to FIG. 9 and FIGS. 10A and 10B.

Referring to FIG. 9 and FIGS. 10A and 10B, in the curved area CA, a first line pattern 222 includes at least one buffer hole 222h. The at least one buffer hole 222h formed in the curved area CA is formed so as not to overlap the 1-1 connection line 181-1 and the 1-2 connection line 181-2. That is, the 1-1 connection line 181-1 and the 1-2 connection line 181-2 are formed only on some areas of the first line pattern 222 in which the at least one buffer hole 222h is not disposed.

Specifically, as shown in FIG. 9, the at least one buffer hole 222h may be disposed between the 1-1 connection line 181-1 and the 1-2 connection line 181-2. Alternatively, the at least one buffer hole 222h may be disposed outside the 1-1 connection line 181-1 and the 1-2 connection line 181-2. In other words, the at least one buffer hole 222h may be disposed on either or both of one side of the 1-1 connection line 181-1 and the other side of the 1-2 connection line 181-2.

In FIG. 10A, in the curved area CA, a buffer hole 222h is formed in a portion of the first line pattern 222. In one embodiment, the buffer hole 222h extends through the first line pattern 222 and exposes a top surface of the lower substrate 111. Here, the buffer hole 222h is between the connection line 181-2 and the connection line 181-1 and do not overlap with the connection lines 181-1, 181-2. Further, as shown, in the straight area SA, the buffer hole 222h is not formed within the first line pattern 222 and therefore, in the illustrated embodiment, the buffer hole 222h is not present in the straight area SA.

On the other hand, as shown in FIG. 9 and FIGS. 10A and 10B, in the straight area SA, at least one buffer hole 222h is not formed in the first line pattern 222.

Meanwhile, as shown in FIG. 10A, no filling member may be disposed in the at least one buffer hole 222h. In other words, an inside of the at least one buffer hole 222h may be an empty space.

Alternatively, as shown in FIG. 10B, a filling member FM having a modulus of elasticity lower than that of the first line pattern 222 may be disposed inside the at least one buffer hole 222h. That is, the filling member FM may be formed of silicone rubber such as polydimethylsiloxane (PDMS) or elastomers such as polyurethane (PU) and polytetrafluoroethylene (PTFE)

That is, in the display device according to another example embodiment of the present disclosure, the filling member FM serving as a buffer may be disposed between the plurality of connection lines 181-1 and 181-2 in the curved area CA.

Accordingly, in the display device according to another example embodiment of the present disclosure, the buffer hole and the filling member distribute stretching stress applied in the curved area. Specifically, when the display device according to another example embodiment of the present disclosure is stretched, stretching stress applied to each of the plurality of connection lines was measured as a maximum of 4.7 MPa. That is, the stretching stress applied to each of the plurality of connection lines was reduced to a maximum of 41% at the same stretching rate. Accordingly, in the display device according to another example embodiment of the present disclosure, a defect of disconnection of the connection lines may be more effectively solved.

Unlike this, as shown in FIG. 10B, a filling member FM having a modulus of elasticity equal to or higher than that of the first line pattern 222 may be disposed inside the at least one buffer hole 222h. That is, the filling member FM may be formed of polyimide (PI), polyacrylate, polyacetate, or the like.

That is, in the display device according to another example embodiment of the present disclosure, the filling member FM serving to limit stretching may be disposed between the plurality of connection lines 181-1 and 181-2 in the curved area CA.

In one embodiment, the filling member FM fills the space defined by the buffer hole 222h. Here, a top surface TS_FM of the filling member FM is flush with a top surface TS_LP of the first line pattern 222. However, this is merely an example and in other embodiments, the top surface TS_FM of the filling member FM is not required to be flush with the top surface TS_LP of the first line pattern 222. For instance, the top surface TS_FM of the filling member FM may be lower than the top surface TS_LP of the first line pattern 222.

Accordingly, in the display device according to another example embodiment of the present disclosure, the buffer hole and the filling member may limit a degree of stretching of the curved area. Specifically, when the display device according to another example embodiment of the present disclosure is stretched, a degree of stretching of the filling member FM having a high modulus of elasticity is relatively low, and accordingly, the degree of stretching of the connection lines may also be limited. Accordingly, in the display device according to another example embodiment of the present disclosure, the degree of stretching of the connection lines is reduced, so that the defect of disconnection of the connection lines may be prevented.

Hereinafter, a display device according to still another example embodiment of the present disclosure will be described. Since there are differences between the display device according to still another example embodiment of the present disclosure and the display device according to another example embodiment of the present disclosure only in terms of buffer holes, this will be described in detail. In addition, in the display device according to still another example embodiment of the present disclosure and the display device according to another example embodiment of the present disclosure, the same reference numerals are used for the same components, and a detailed description thereof will be omitted.

### Still Another Example Embodiment of the Present Disclosure

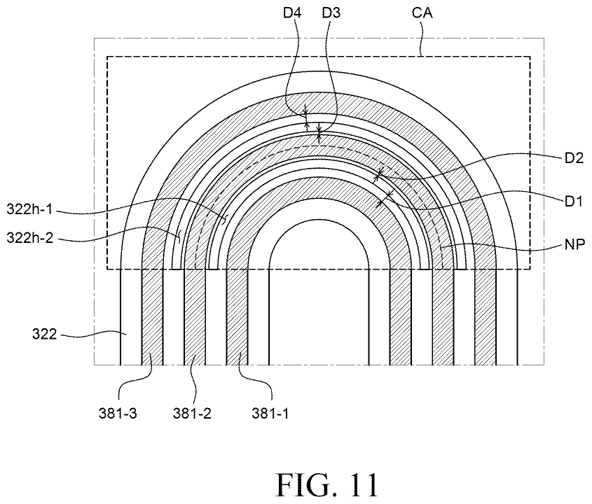

FIG. 11 is a view illustrating connection lines of a display device according to still another example embodiment of the present disclosure.

Referring to FIG. 11, a plurality of connection lines may be disposed on one first line pattern 322. Specifically, a 1-1 connection line 381-1, a 1-2 connection line 381-2, and a 1-3 connection line 381-3 may be sequentially disposed on one first line pattern 322 in each of the straight area SA and the curved area CA. In other words, on one first line pattern 322, one side connection line corresponding to the 1-1 connection line 381-1, an intermediate connection line corresponding to the 1-2 connection line 381-2, and the other side connection line 1-3 corresponding to the 1-3 connection line 381-3 may be disposed. The 1-1 connection line 381-1, the 1-2 connection line 381-2, and the 1-3 connection line 381-3 disposed on one first line pattern 322 may be disposed at a predetermined interval and with the same shape.

In addition, the 1-1 connection line 381-1, the 1-2 connection line 381-2, and the 1-3 connection line 381-3 that are disposed on one first line pattern 322 may transmit different voltages. For example, if the 1-1 connection line 381-1 serves as a gate line transmitting a gate voltage, the 1-2 connection line 381-2 may be a high potential voltage line transmitting a high potential voltage, and the 1-3 connection line 381-3 may be a low potential voltage line transmitting a low potential voltage. However, functions of the 1-1 connection line 381-1, the 1-2 connection line 381-2, and the 1-3 connection line 381-3 that are disposed on one first line pattern 322 are not limited thereto, and may be variously changed according to necessity in design.

In FIG. 11, the first connection line has been described in detail, and the second connection line is not specifically illustrated. However, the second connection line may also include a 2-1 connection line, a 2-2 connection line, and a 2-3 connection line that are disposed on one first line pattern in the same manner as the first connection line. In addition, the 2-1 connection line, the 2-2 connection line, and the 2-3 connection line disposed on one first line pattern may be disposed at a predetermined interval and with the same shape.

In addition, since the first line pattern 322 in the curved area CA is curved with a constant curvature, the first line pattern 322 in the curved area CA may form a neutral plane NP.

As described above, the neutral plane NP may be a virtual plane that is not subjected to stress because compressive force and tensile force applied to the first line pattern 322 cancel each other out when the first line pattern 322 is stretched. Accordingly, in order to reduce or minimize compressive force and tensile force that are applied to the 1-1 connection line 381-1, the 1-2 connection line 381-2, and the 1-3 connection line 381-3, the 1-2 connection line 381-2 may be positioned on the neutral plane NP. Accordingly, by overlapping the 1-2 connection line 381-2 and the neutral plane NP, Cracks occurring in the 1-1 connection line 381-1, the 1-2 connection line 381-2, and the 1-3 connection line 381-3 can be reduced or minimized.

Also, in the curved area CA in the display device according to still another example embodiment of the present disclosure, the first line pattern 322 includes at least one or more buffer holes 322h-1 and 322h-2. The at least one or more buffer holes 322h-1 and 322h-2 formed in the curved area CA are formed so as not to overlap the 1-1 connection line 381-1, the 1-2 connection line 381-2, and the 1-3 connection line. That is, the 1-1 connection line 381-1, the 1-2 connection line 381-2, and the 1-3 connection line 381-3 are disposed only on some areas of the first line pattern 322 in which the at least one or more buffer holes 322h-1 and 322h-2 are not disposed.

Specifically, as shown in FIG. 11, the at least one or more buffer holes 322h-1 and 322h-2 include a first buffer hole 322h-1 and a second buffer hole 322h-2. The first buffer hole 322h-1 may be disposed between the 1-1 connection line 381-1 and the 1-2 connection line 381-2, and the second buffer hole 322h-2 may be disposed between the 1-2 connection line 381-2 and the 1-3 connection line 381-3. Alternatively, the at least one or more buffer holes 322h-1 and 322h-2 may be disposed outside the 1-1 connection line 381-1, the 1-2 connection line 381-2, and the 1-3 connection line 381-3. In other words, the at least one or more buffer holes 322h-1 and 322h-2 may be disposed on either or both of one side of the 1-1 connection line 381-1 and the other side of the 1-3 connection line 381-3.

In addition, each of the first buffer hole 322h-1 and the second buffer hole 322h-2 may be formed to be adjacent to the 1-2 connection line 381-2. Specifically, the first buffer hole 322h-1 may be disposed closer to the 1-2 connection line 381-2 than the 1-1 connection line 381-1, and the second buffer hole 322h-2 may be disposed closer to the 1-2 connection line 381-2 than the 1-3 connection line 381-3.

More specifically, a distance D2 between the first buffer hole 322h-1 and the 1-2 connection line 381-2 is shorter than a distance D1 between the first buffer hole 322h-1 and the 1-1 connection line 381-1. In addition, a distance D3 between the second buffer hole 322h-2 and the 1-2 connection line 381-2 is shorter than a distance D4 between the second buffer hole 322h-2 and the 1-3 connection line 381-3.

By disposing the first buffer hole 322h-1 and the second buffer hole 322h-2 in the form as described above, strength of an inner area in the first line pattern 322, in which the 1-1 connection line 381-1 is disposed, and an outer area in the first line pattern 322, in which the 1-3 connection line 381-3 is disposed may increase. Stretching stress is concentrated on the inner area and the outer area of the first line pattern in stretching of the display device. Thus, by increasing the strength of the inner area and the outer area of the first line pattern 322 through the disposition of the first buffer hole 322h-1 and the second buffer hole 322h-2 described above, so that stretching reliability of the display device may be improved.

On the other hand, as shown in FIG. 11, in the straight area SA, at least one or more buffer holes 322h-1 and 322h-2 are not formed in the first line pattern 322.

Meanwhile, no filling member may be disposed in the at least one or more buffer holes 322h-1 and 322h-2. In other words, an inside of the at least one or more buffer hole 322h-1 and 322h-2 may be an empty space.

Alternatively, the inside of the at least one or more buffer holes 322h-1 and 322h-2 may be filled with a filling member having a modulus of elasticity lower than that of the first line pattern 322. That is, it may be formed of silicone rubber such as polydimethylsiloxane (PDMS) or elastomers such as polyurethane (PU) and polytetrafluoroethylene (PTFE).

That is, in the display device according to still another example embodiment of the present disclosure, a filling member serving as a buffer may be disposed between the plurality of connection lines 381-1 and 181-2 in the curved area CA.

Accordingly, in the display device according to still another example embodiment of the present disclosure, the buffer hole and the filling member may distribute stretching stress applied in the curved area.

Unlike this, a filling member having a modulus of elasticity equal to or higher than that of the first line pattern 322 may be disposed inside the at least one or more buffer holes 322h-1 and 322h-2. That is, the filling member FM may be formed of polyimide (PI), polyacrylate, polyacetate, or the like.

That is, in the display device according to still another example embodiment of the present disclosure, a filling member serving to limit stretching may be disposed between the plurality of connection lines 381-1 and 181-2 in the curved area CA.

Accordingly, in the display device according to still another example embodiment of the present disclosure, a degree of stretching of the connection lines is reduced, so that a defect of disconnection of the connection lines can be prevented.

The example embodiments of the present disclosure can also be described as follows:

A display device according to an example embodiment of the present disclosure may include a stretchable lower substrate; a pattern layer disposed on the lower substrate and including a plurality of plate patterns and a plurality of line patterns; a plurality of pixels disposed on each of the plurality of plate patterns; and a plurality of connection lines connecting the plurality of pixels, wherein the plurality of connection lines are disposed on each of the plurality of line patterns, so that stretching reliability may be improved.

The plurality of connection lines disposed on each of the plurality of line patterns may transmit different voltages.

Each of the plurality of line patterns may include a straight area extending in a straight line and a curved area extending in a curved line.

In the curved area of each of the plurality of line patterns, a buffer hole that may not overlap the plurality of connection lines is formed.

The buffer hole may be filled with a filling member having a modulus of elasticity lower than a modulus of elasticity of the plurality of line patterns.

The buffer hole may be filled with a filling member having a modulus of elasticity higher than or equal to a modulus of elasticity of the plurality of line patterns.

The plurality of connection lines disposed on each of the plurality of line patterns may include one side connection line and the other side connection line.

At least one buffer hole may be formed between the one side connection line and the other side connection line.

The at least one buffer hole may be filled with an elastic polymer.

The plurality of connection lines disposed on each of the plurality of line patterns include, one side connection line, an intermediate connection line, and the other side connection line that may be sequentially disposed.

A first buffer hole may be formed between the one side connection line and the intermediate connection line, and a second buffer hole is formed between the intermediate connection line and the other side connection line.

The first buffer hole may be disposed closer to the intermediate connection line than the one side connection line, and the second buffer hole is disposed closer to the intermediate connection line than the other side connection line.

Each of the first buffer hole and the second buffer hole is filled with a filling member having a modulus of elasticity lower than a modulus of elasticity of the plurality of line patterns.

Each of the first buffer hole and the second buffer hole is filled with a filling member having a modulus of elasticity higher than or equal to a modulus of elasticity of the plurality of line patterns.

The intermediate connection line may overlap a neutral plane of a curved area of each of the plurality of line patterns.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a stretchable substrate;
a pattern layer disposed on the substrate and including a plurality of plate patterns and a plurality of line patterns;
a plurality of pixels disposed on each of the plurality of plate patterns; and
a plurality of connection lines coupling the plurality of pixels,
wherein the plurality of connection lines are disposed on each of the plurality of line patterns.

2. The display device of claim 1, wherein the plurality of connection lines disposed on each of the plurality of line patterns transmit different voltages.

3. The display device of claim 1, wherein each of the plurality of line patterns includes a straight area extending in a straight line and a curved area extending in a curved line.

4. The display device of claim 1, further including:
a buffer hole is disposed that does not overlap the plurality of connection lines.

5. The display device of claim 4, wherein the buffer hole is filled with a filling member having a modulus of elasticity lower than a modulus of elasticity of the plurality of line patterns.

6. The display device of claim 4, wherein the buffer hole is filled with a filling member having a modulus of elasticity higher than or equal to a modulus of elasticity of the plurality of line patterns.

7. The display device of claim 1, wherein the plurality of connection lines disposed on each of the plurality of line patterns include one side connection line and the other side connection line.

8. The display device of claim 7, wherein at least one buffer hole is formed between the one side connection line and the other side connection line.

9. The display device of claim 8, wherein the at least one buffer hole is filled with an elastomer.

10. The display device of claim 1,
wherein the plurality of connection lines disposed on each of the plurality of line patterns include:
one side connection line, an intermediate connection line, and the other side connection line that are sequentially disposed.

11. The display device of claim 10,
wherein a first buffer hole is formed between the one side connection line and the intermediate connection line, and
wherein a second buffer hole is formed between the intermediate connection line and the other side connection line.

12. The display device of claim 11,
wherein the first buffer hole is disposed closer to the intermediate connection line than the one side connection line, and
wherein the second buffer hole is disposed closer to the intermediate connection line than the other side connection line.

13. The display device of claim 11, wherein each of the first buffer hole and the second buffer hole is filled with a filling member having a modulus of elasticity lower than a modulus of elasticity of the plurality of line patterns.

14. The display device of claim 11, wherein each of the first buffer hole and the second buffer hole is filled with a filling member having a modulus of elasticity higher than or equal to a modulus of elasticity of the plurality of line patterns.

15. The display device of claim 10, wherein the intermediate connection line overlaps a neutral plane of a curved area of each of the plurality of line patterns.

16. A display device, comprising:
a substrate;
a plurality of plate patterns on the substrate, each plate pattern spaced apart from each other;
at least one pixel disposed on each plate pattern;
at least one connection line coupled between adjacent pixels; and
at least one line pattern disposed beneath the at least one connection line.

17. The display device of claim 16, wherein the at least one connection line has a first curvature at a first area and a second curvature at a second area, the second area being contiguous to the first area,
wherein the at least one connection line includes a first connection line and a second connection line adjacent to and spaced apart from the first connection line,
wherein the first area has a constant first curvature that is greater than zero, and
wherein the second area has a constant second curvature that is equal to zero.

18. The display device of claim 17, wherein in the first area, the at least one line pattern includes a buffer hole, the buffer hole extending through the at least one line pattern and exposing the substrate.

19. The display device of claim 18, wherein the buffer hole is between the first connection line and the second connection line.

20. The display device of claim 19, comprising:
a filling member disposed in the buffer hole,
wherein a top surface of the filling member is flush with a top surface of the at least one line pattern.
